(19) United States
(12) Patent Application Publication
(10) Pub. No.: US 2025/0385140 A1
(43) Pub. Date: Dec. 18, 2025

(54) S-PARAMETER DESIGN IN BACKSIDE POWER DISTRIBUTION NETWORK

(71) Applicant: International Business Machines Corporation, Armonk, NY (US)

(72) Inventors: Huimei Zhou, Albany, NY (US); Chen Zhang, Santa Clara, CA (US); Miaomiao Wang, Albany, NY (US); John Knickerbocker, Monroe, NY (US); Huiming Bu, Glenmont, NY (US)

(21) Appl. No.: 18/742,029

(22) Filed: Jun. 13, 2024

(51) Int. Cl. H01L 21/66; G01R 27/28; H01L 23/498; H01L 29/06; H01L 29/423

(52) U.S. Cl. CPC H01L 22/34; G01R 27/28; H01L 23/49838; H10D 30/6735; H10D 62/118

(57) ABSTRACT

A semiconductor device is provided for executing S-parameter testing. The semiconductor device includes a first layer comprising a device under test (DUT), a second layer including metallization, a third layer including a backside power distribution network (BSPDN), a signal pad and a connecting structure connecting the DUT to the signal pad via the metallization. The connecting structure includes a first connecting section by which the DUT is connected to the metallization and a second connecting section that extends from the metallization, through the first layer and through the third layer to the signal pad and by which the metallization is connected to the signal pad.

### BACKGROUND

The present disclosure generally relates to fabrication methods and resulting structures for semiconductor devices. More specifically, the present disclosure relates to an S-parameter design in a backside power deliver network (BSPDN) of a semiconductor device.

Electrical devices can be used to receive and transmit radio frequency (RF) and microwave signals. For example, RF devices may include back-end-of-line (BEOL) devices, such as vertical natural capacitors (VNCAP's), metal-insulator-metal capacitors (MIMCAP), BEOL metal resistors, inductors, T-coils, transformers and interconnect transmission lines. RF devices may be characterized or measured for performance using various network parameters such as scattering parameters (“S-parameters”). Processes of extracting intrinsic device network parameters from raw, measured network parameters of RF devices can be referred to as de-embedding.

### SUMMARY

According to an aspect of the disclosure, a semiconductor device is provided for executing S-parameter testing. The semiconductor device includes a first layer comprising a device under test (DUT), a second layer including metallization, a third layer including a backside power distribution network (BSPDN), a signal pad and a connecting structure connecting the DUT to the signal pad via the metallization. The connecting structure includes a first connecting section by which the DUT is connected to the metallization and a second connecting section that extends from the metallization, through the first layer and through the third layer to the signal pad and by which the metallization is connected to the signal pad. In additional or alternative embodiments, the semiconductor device provides for a novel S-parameter design that is compatible with BSPDN processing.

According to an aspect of the disclosure, a semiconductor device is provided for executing S-parameter testing. The semiconductor device includes a first layer including first and second regions and first and second gates each of which crosses the first and second regions, a second layer overlying the first layer and including metallization, a third layer underlying the first layer and including a backside power distribution network (BSPDN), a signal pad, a first connecting structure connecting a section of the first gate defined between the first and second regions to the metallization and a second connecting structure connecting the metallization to the signal pad via a sub-section of the first region defined between the first and second gates. In additional or alternative embodiments, the semiconductor device provides for a novel S-parameter design that is compatible with BSPDN processing.

According to an aspect of the disclosure, a method of conducting S-parameter testing of a semiconductor device is provided. The method includes connecting a device under test (DUT) to a backside signal pad via a first connection of the DUT to frontside metallization and a second connection of the frontside metallization to the backside signal pad, executing first runs of the S-parameter testing, compiling baseline performance data of the DUT and isolating wiring performance data of DUT wiring from the baseline performance data. The method therefore provides for S-parameter testing of the DUT with a device in which the signal pads are disposed below the backside power distribution network (BSPDN).

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a perspective view of a semiconductor device with backside signal pads for S-parameter testing in accordance with one or more embodiments;

FIG. 2 is a top-down view of a semiconductor device with a backside signal pad for S-parameter testing in accordance with one or more embodiments;

FIG. 3A is a side view of the semiconductor device of FIG. 2 along the perspective defined by line 3A-3A in FIG. 2 in accordance with one or more embodiments;

FIG. 3B is a side view of the semiconductor device of FIG. 2 along the perspective defined by line 3B-3B in FIG. 2 in accordance with one or more embodiments;

FIG. 4A is a side view of the semiconductor device of FIG. 2 in an open condition along the perspective defined by line 4A-4A in FIG. 2 in accordance with one or more embodiments;

FIG. 4B is a side view of the semiconductor device of FIG. 2 in an open condition along the perspective defined by line 3A-3A in FIG. 2 in accordance with one or more embodiments;

FIG. 5 is a side view of the semiconductor device of FIG. 2 in a frontside shorted condition along the perspective defined by line 4A-4A in FIG. 2 in accordance with one or more embodiments;

FIG. 6 is a collection of side views of the semiconductor device of FIG. 2 in a backside shorted condition along the perspectives defined by lines 3A-3A, 3B-3B and 4A-4A in FIG. 2 in accordance with one or more embodiments;

FIG. 7 is a top-down view of a semiconductor device with a backside signal pad and multiple second connection structures for S-parameter testing in accordance with one or more embodiments;

FIG. 8A is a side view of the semiconductor device of FIG. 7 along the perspective defined by line 8A-8A in FIG. 7 in accordance with one or more embodiments;

FIG. 8B is a side view of the semiconductor device of FIG. 7 along the perspective defined by line 8B-8B in FIG. 7 in accordance with one or more embodiments;

FIG. 8C is a side view of the semiconductor device of FIG. 7 along the perspective defined by line 8C-8C in FIG. 7 in accordance with one or more embodiments;

FIG. 9 is a flow diagram illustrating a method of conducting S-parameter testing of a semiconductor device in accordance with one or more embodiments; and

FIG. 10 is a flow diagram illustrating a method of S-parameter testing in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided for executing S-parameter testing. The semiconductor device includes a first layer comprising a device under test (DUT), a second layer including metallization, a third layer including a backside power distribution network (BSPDN), a signal pad and a connecting structure connecting the DUT to the signal pad via the metallization. The connecting structure includes a first connecting section by which the DUT is connected to the metallization and a second connecting section that extends from the metallization, through the first layer and through the third layer to the signal pad and by which the metallization is connected to the signal pad. In additional or alternative embodiments, the semiconductor device provides for a novel S-parameter design that is compatible with BSPDN processing.

The first layer is a middle-of-line (MOL) layer, the third layer underlies the MOL layer and the signal pad underlies the third layer to define the signal pad as being disposed below the third layer (i.e., below the BSPDN).

The signal pad includes a first signal pad and a second signal pad and the connecting structure includes a first connecting structure connecting the DUT to the first signal pad via the metallization and a second connecting structure connecting the DUT to the second signal pad via the metallization. The first and second connecting structures thus provide for respective connections between the DUT and the first and second signal pads.

The semiconductor device further includes ground pads and additional connecting structures respectively connecting the metallization to each of the ground pads to provide for a complete circuit assembly.

The first layer includes a semiconductor material and an electrically insulating material underlying the semiconductor material and the BSPDN of the third layer underlies the electrically insulating material whereby the semiconductor device is compatible with lithographic processes and disposes the signal pad(s) below the BSPDN.

According to an aspect of the disclosure, a semiconductor device is provided for executing S-parameter testing. The semiconductor device includes a first layer including first and second regions and first and second gates each of which crosses the first and second regions, a second layer overlying the first layer and including metallization, a third layer underlying the first layer and including a backside power distribution network (BSPDN), a signal pad, a first connecting structure connecting a section of the first gate defined between the first and second regions to the metallization and a second connecting structure connecting the metallization to the signal pad via a sub-section of the first region defined between the first and second gates. In additional or alternative embodiments, the semiconductor device provides for a novel S-parameter design that is compatible with BSPDN processing.

The section of the first gate includes nanosheets and high-k metal gate material surrounding the nanosheets such that the semiconductor device is complementary-metal-oxide-semiconductor (CMOS) compatible.

The sub-section of the first region includes dielectric material surrounding a portion of the second connecting structure so electrically isolate the second connecting structure.

The first layer is a middle-of-line (MOL) layer, the second layer includes a back-end-of-line (BEOL) layer to which a carrier wafer is attachable, the third layer underlies the MOL layer and the signal pad underlies the third layer to define the signal pad as being disposed below the third layer (i.e., below the BSPDN).

The semiconductor device further includes interlayer dielectric (ILD) interposed between the first layer and the second layer. The first connecting structure includes a gate (CB) contact disposed in contact with the section of the first gate and a first additional contact disposed within the ILD and in contact with the CB contact and the metallization and the second connecting structure includes a second additional contact disposed within the ILD and in contact with the metallization, CA/RV/BV contacts disposed in contact with the second additional contact and a backside (E1) metal disposed in contact with the CA/RV/BV contacts and the BSPDN. The first and second connecting structures are therefore capable of connecting the first gate with the signal pad via the metallization.

The first and second connecting structures are openable for conducting S-parameter testing in which wiring performance is isolated.

The semiconductor device further includes a metallization short for conducting S-parameter testing in which wiring performance is isolated.

The semiconductor device further includes a BSPDN short for conducting S-parameter testing in which wiring performance is isolated.

The second connecting structure is provided as multiple backside second connecting structures for multiple signal pad connections.

The first connecting structure and at least one of the multiple backside second connecting structures are openable for conducting S-parameter testing in which wiring performance is isolated.

According to an aspect of the disclosure, a method of conducting S-parameter testing of a semiconductor device is provided. The method includes connecting a device under test (DUT) to a backside signal pad via a first connection of the DUT to frontside metallization and a second connection of the frontside metallization to the backside signal pad, executing first runs of the S-parameter testing, compiling baseline performance data of the DUT and isolating wiring performance data of DUT wiring from the baseline performance data. The method therefore provides for S-parameter testing of the DUT with a device in which the signal pads are disposed below the backside power distribution network (BSPDN).

The isolating of the wiring performance includes opening the first connection and the second connection, executing second runs of the S-parameter testing, optionally compiling open case performance data of the DUT, shorting the semiconductor device, executing third runs of the S-parameter testing, optionally compiling shorted case performance data of the DUT and calculating updated performance data of the DUT by removing the open case performance data of the DUT and the shorted case performance data of the DUT from the baseline performance data of the DUT. The method therefore provides for S-parameter testing of the DUT as well as S-parameter testing of the DUT in which wiring performance is isolated.

The shorting includes one of frontside shorting and backside shorting for conducting S-parameter testing in which wiring performance is isolated in multiple different embodiments.

The connecting is executed such that the second connection of the frontside metallization to the backside signal pad is provided as multiple second connections for multiple signal pad connections.

The isolating of the wiring performance includes opening the first connection and the multiple second connections, executing second runs of the S-parameter testing, shorting the semiconductor device and executing third runs of the S-parameter testing. The method therefore provides for S-parameter testing of the DUT as well as S-parameter testing of the DUT in which wiring performance is isolated.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, an S-parameter can be used in RF and microwave applications to assist in continued development of new high-frequency circuit designs. Where an effect of input impedance of a device is being measured or simulated during circuit design, it is often necessary to know the S-parameters of the device at various frequencies. These S-parameters at each of the frequencies can then be used to calculate input and output impedances on each side of a network of the device as functions of those frequencies. Notably, de-embedding of S-parameters refers to removing the effects of a test fixture, filter or amplifier when gathering measurements for a device under test (DUT). The benefits of de-embedding S-parameters are that it becomes possible to eliminate the S-parameters from measurements and simulations to thereby allow for relatively easy comparisons between simulations and experiments.

Presently, there is no way to consider S-parameters in a circuit design of an electrical device with a BSPDN. This is because signal pads for S-parameter measurements are typically provided above the M1 level of a circuit design and thus require specially designed bridges to the BSPDN as well as de-embedding designs that are associated with whole S-parameter characterization systems to accomplish de-embedding wiring related effects.

Turning now to an overview of the aspects of the disclosure, one or more embodiments of the disclosure address the above-described shortcomings of the prior art by providing a circuit design with an S-parameter scheme with a DUT within a front-end-of-line (FEOL) region and a backside back-end-of-line (BEOL) network that includes two signal pads connected to the DUT through various contact and via elements.

The above-described aspects of the disclosure address the shortcomings of the prior art by providing for a semiconductor device for executing S-parameter testing. The semiconductor device includes a first layer that includes a device under test (DUT), a second layer that includes metallization, a third layer that includes a backside power distribution network (BSPDN), a signal pad and a connecting structure. The connection structure connects the DUT to the signal pad via the metallization. The connecting structure includes a first connecting section by which the DUT is connected to the metallization and a second connecting section that extends from the metallization, through the first layer and through the third layer to the signal pad and by which the metallization is connected to the signal pad.

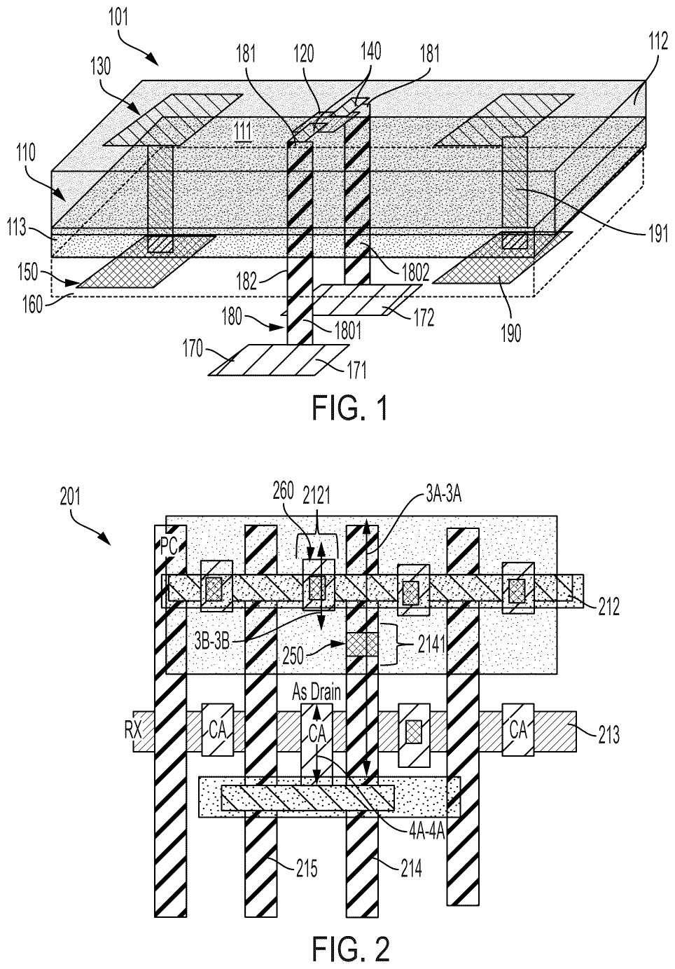

Turning now to a more detailed description of aspects of the present disclosure, FIG. 1 is a perspective view of a semiconductor device 101 for executing S-parameter testing. The semiconductor device 101 includes a first layer 110 that includes a DUT 120, a second layer 130 that includes metallization 140, a third layer 150 that includes a BSPDN 160, a signal pad 170 and a connecting structure 180. The connecting structure 180 connects the DUT 120 to the signal pad 170 via the metallization 140. The connecting structure 180 includes a first connecting section 181 by which the DUT 120 is connected to the metallization 140 and a second connecting section 182 that extends from the metallization 140 through the first layer 110 and through the third layer 150 to the signal pad 170 and by which the metallization 140 is connected to the signal pad 170. The first layer 110 can be provided as a middle-of-line (MOL) layer 111 and can include a semiconductor material layer 112 and an electrical insulating layer 113 underlying the semiconductor material layer 112; the second layer 130 can include or be provided as a back-end-of-line (BEOL) layer, and the third layer 150 underlies the MOL layer 111 whereby the BSPDN 160 underlies the electrical insulating layer 113 and the signal pad 170 underlies the third layer 150. The signal pad 170 can include or be provided as a first signal pad 171 and a second signal pad 172 and, in these or other cases, the connecting structure 180 can include or be provided as a first connecting structure 1801 connecting the DUT 120 to the first signal pad 171 via the metallization 140 and a second connecting structure 1802 connecting the DUT 120 to the second signal pad 172 via the metallization 140. The semiconductor device 101 can further include ground pads 190 and additional connecting structures 191 respectively connecting the metallization 140 to each of the ground pads 190.

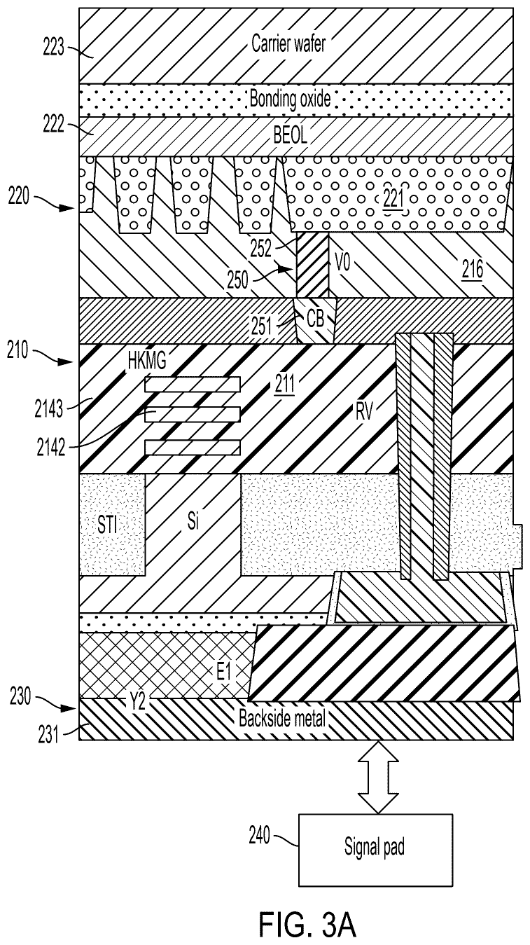

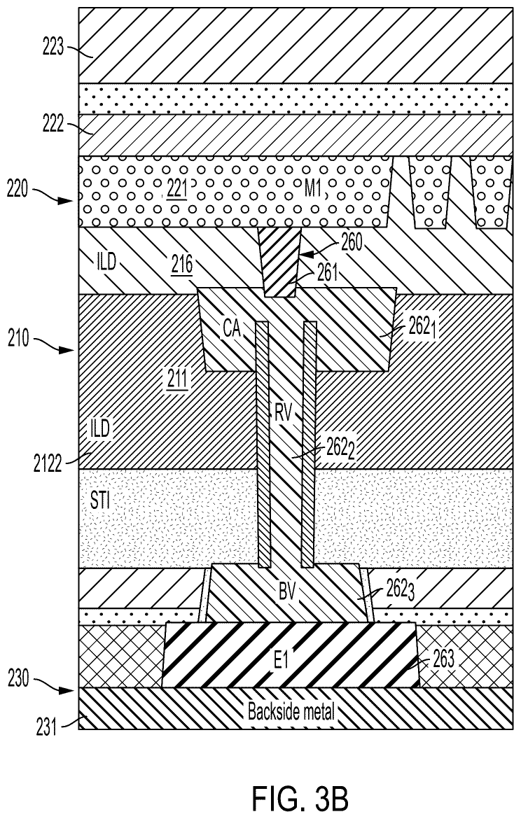

With reference to FIG. 2 and FIGS. 3A and 3B, a semiconductor device 201 is provided for executing S-parameter testing. The semiconductor device 201 includes a first layer 210, a second layer 220, a third layer 230, a signal pad 240, a first connecting structure 250 and a second connecting structure 260. The first layer 210 can be provided as an MOL layer 211 and includes first region 212, second channel region 213, first gate 214 and second gate 215. The first gate 214 crosses the first region 212 and crosses the second channel region 213. The second gate 215 crosses the first region 212 and crosses the second channel region 213. The second layer 220 includes metallization 221 that can be in a form of an M1 layer and can include a BEOL layer 222 overlying the metallization 221 and the first layer 210 as well as a wafer carrier 223 overlying and attached to the BEOL layer 222. The third layer 230 underlies the first layer 210 and includes a backside BSPDN 231 (hereinafter referred to as a “BSPDN 231”). The signal pad 240 underlies the third layer 230 and is connected to the BSPDN 231.

The first connecting structure 250 connects a section 2141 of the first gate 214, which is defined between the first region 212 and the second channel region 213, to the metallization 221. The section 2141 of the first gate 214 can include nanosheets 2142 and high-k metal gate material 2143 surrounding the nanosheets 2142. The second connecting structure 260 connects the metallization 221 to the signal pad 240 via a section 2121 of the first region 212, which is defined between the first gate 214 and the second gate 215. The section 2121 of the first region 212 can include dielectric material 2122 surrounding at least a portion of the second connecting structure 260.

In accordance with one or more embodiments, the semiconductor device 201 can include interlayer dielectric (ILD) 216, which is interposed between the first layer 210 and the second layer 220. In these or other cases, the first connecting structure 250 can include a gate (CB) contact 251 that is disposed in contact with the section 2141 of the first gate 214 and a first additional contact 252 that is disposed within the ILD 216 and in contact with the CB contact 251 and the metallization 221. Also, in these or other cases, the second connecting structure 260 can include a second additional contact 261 disposed within the ILD 216 and in contact with the metallization 221, CA and RV and BV contacts 262_{1, 2, 3} sequentially disposed in contact with the second additional contact 261 and a backside (E1) contact 263 disposed in contact with the CA and RV and BV contacts 262_{1, 2, 3} and the BSPDN 231.

In accordance with one or more embodiments, the ILD 216 can include an electrically insulating dielectric with low (≤1 watt/M K) thermal conductivity or an electrical insulating dielectric with higher (>1 to 10 Watts/M K) thermal conductivity.

With the configuration of FIG. 2 and FIGS. 3A and 3B, the silicon high-k metal gate material 2143 acts or serves as a DUT in a black box and its connection to the signal pad 240 by way of the first connecting structure 250 and the second connecting structure 260 allows for first runs of S-parameter testing.

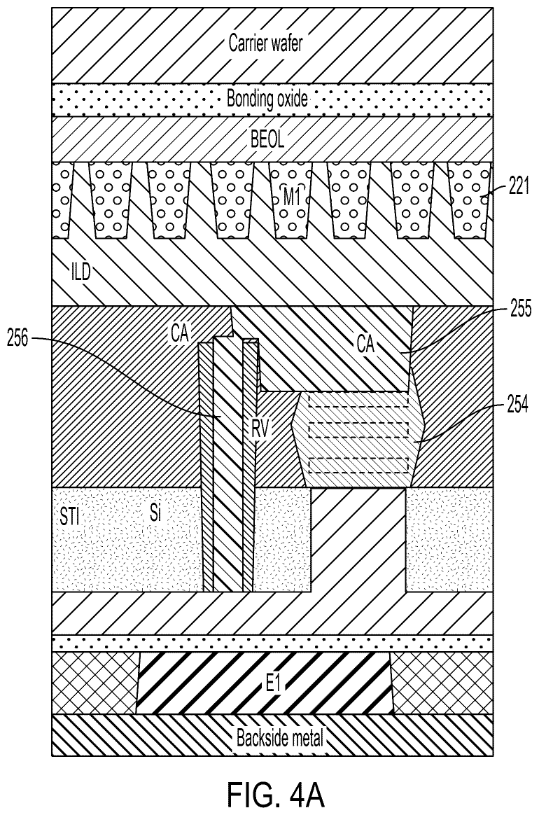

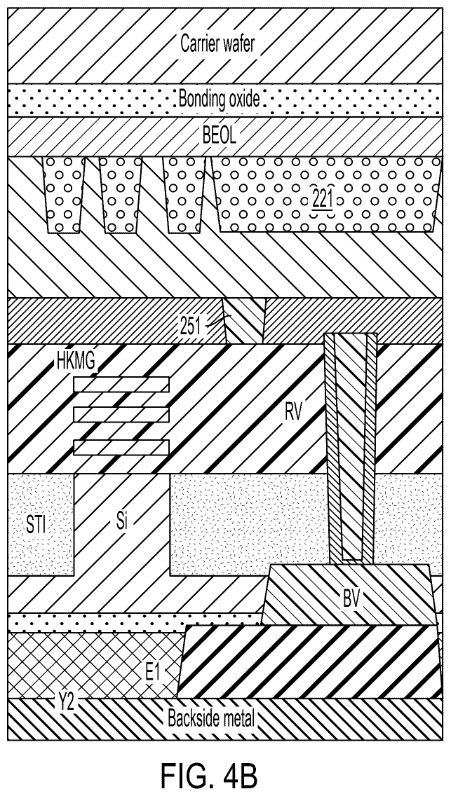

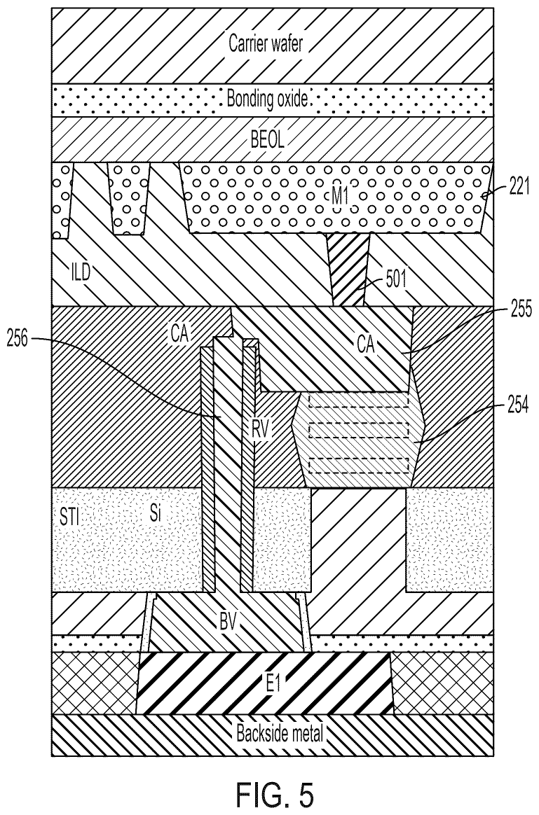

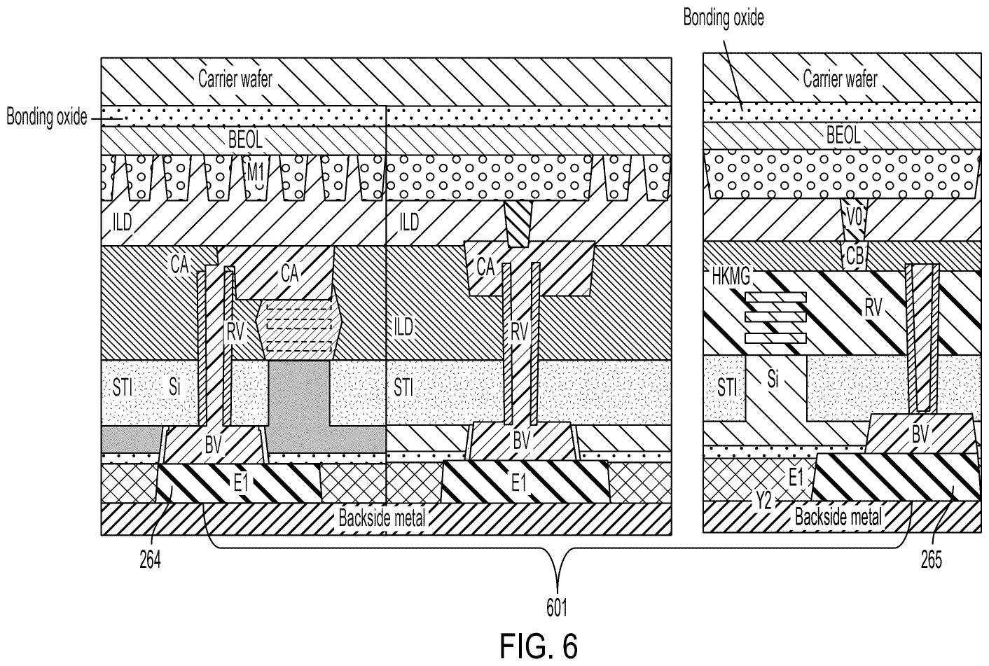

With continued reference to FIG. 2 and FIGS. 3A and 3B and with additional reference to FIGS. 4A and 4B and to FIGS. 5 and 6, the S-parameter testing of the DUT of FIGS. 2 and 3 needs to be appended with further S-parameter testing in which wiring impact is removed from consideration so that the performance of the DUT can be isolated. As shown in FIGS. 4A and 4B, second runs of S-parameter testing are executed with the first additional contact 252 and a BV contact in electrical communication with epitaxy 254 via CA contact 255 and RV contact 256 are removed to open the first connecting structure 250 (see FIG. 3A) and the second connecting structure 260 (see FIG. 3B) and to thereby form an open case of the semiconductor device 201. As shown in FIGS. 5 and 6, third runs of S-parameter testing are executed with the semiconductor device 201 in a shorted condition. The shorted condition can be achieved with a frontside metallization short through the metallization 221 by adding an additional frontside connection 501 to connect the metallization 221 with the epitaxy 254 via CA contact 255 and via the additional frontside connection 501 (see FIG. 5) or with a backside BSPDN short by adding a wiring connection 601 between the E1 contact 264 and another E1 contact 265 (see FIG. 6).

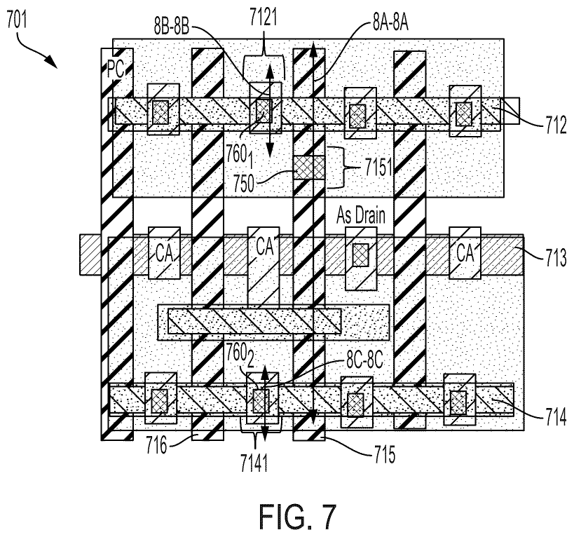

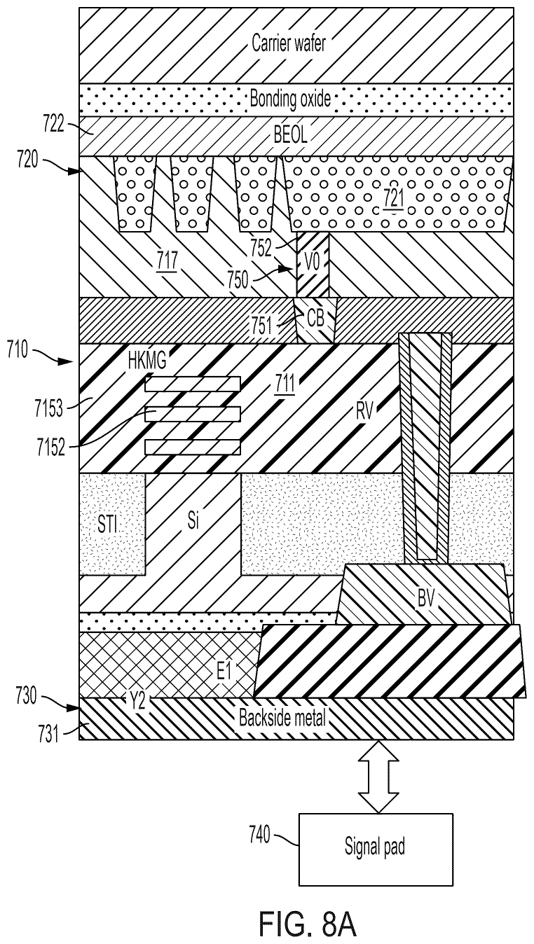

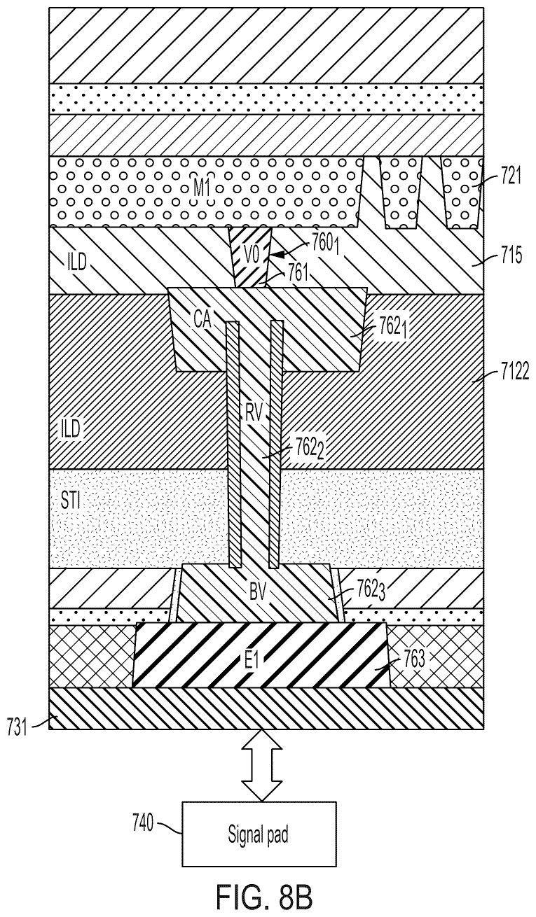

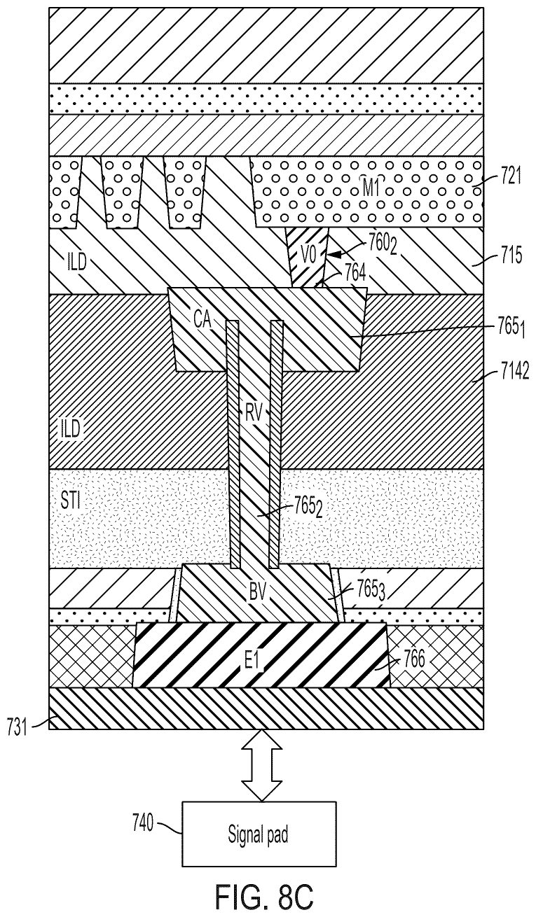

With reference to FIG. 7 and FIGS. 8A, 8B and 8C, a semiconductor device 701 is provided for executing S-parameter testing. The semiconductor device 701 includes a first layer 710, a second layer 720, a third layer 730, a signal pad 740, a first connecting structure 750 and multiple backside connecting structures 760₁ (see FIG. 8B), 760₂ (see FIG. 8C). The first layer 710 can be provided as an MOL layer 711 and includes first region 712, second channel region 713, third region 714, first gate 715 and second gate 716. The first gate 715 crosses the first region 712, crosses the second channel region 713 and crosses the third region 714. The second gate 716 crosses the first region 712, crosses the second channel region 713 and crosses the third region 714. The second layer 720 includes metallization 721 that can be in a form of an M1 layer and can include a BEOL layer 722 overlying the metallization 721 and the first layer 710 as well as a wafer carrier 723 overlying and attached to the BEOL layer 722. The third layer 730 underlies the first layer 710 and includes a backside BSPDN 731 (hereinafter referred to as a “BSPDN 731”). The signal pad 740 underlies the third layer 730 and is connected to the BSPDN 731.

The first connecting structure 750 connects a section 7151 of the first gate 715, which is defined between the first region 712 and the second channel region 713, to the metallization 721. The section 7151 of the first gate 715 can include nanosheets 7152 and silicon high-k metal gate material 7153 surrounding the nanosheets 7152. The backside connecting structure 760₁ connects the metallization 721 to the signal pad 740 via a section 7121 of the first region 712, which is defined between the first gate 715 and the second gate 716. The section 7121 of the first region 712 can include dielectric material 7122 surrounding at least a portion of the second backside connecting structure 7601. The second backside connecting structure 760₂ connects the metallization 721 to another signal pad 740 via a section 7141 of the third region 714, which is defined between the first gate 715 and the second gate 716. The section 7141 of the third region 714 can include dielectric material 7142 surrounding at least a portion of the second backside connecting structure 760₂.

In accordance with one or more embodiments, the semiconductor device 701 can include interlayer dielectric (ILD) 717, which is interposed between the first layer 710 and the second layer 720. In these or other cases, the first connecting structure 750 can include a gate (CB) contact 751 that is disposed in contact with the section 7151 of the first gate 715 and a first additional contact 752 that is disposed within the ILD 717 and in contact with the CB contact 751 and the metallization 721. Also, in these or other cases, the second backside connecting structure 760₁ can include a second additional contact 761 disposed within the ILD 717 and in contact with the metallization 721, CA and RV and BV contacts 762_{1, 2, 3} sequentially disposed in contact with the second additional contact 761 and an E1 contact 763 disposed in contact with the CA and RV and BV contacts 762_{1, 2, 3} and the BSPDN 731. Further, in these or other cases, the second backside connecting structure 760₂ can include another second additional contact 764 disposed within the ILD 717 and in contact with the metallization 721, CA and RV and BV contacts 765_{1, 2, 3} sequentially disposed in contact with the another second additional contact 764 and an E1 contact 766 disposed in contact with the CA and RV and BV contacts 765_{1, 2, 3} and the BSPDN 731.

With the configuration of FIGS. 7 and 8, the silicon high-k metal gate channel material 7153 acts or serves as a DUT in a black box, and its connection to the signal pad 740 by way of the first connecting structure 750 and the multiple second connecting structures 760₁, 760₂ allows for first runs of S-parameter testing.

As above, the S-parameter testing of the DUT of FIGS. 7 and 8 needs to be appended with further S-parameter testing in which wiring performance is removed from consideration so that the performance of the DUT can be isolated. For example, this can be done by the first connecting structure 750 and the multiple second connecting structures 760₁, 760₂ being openable (i.e., by the first additional contact 752 being removed).

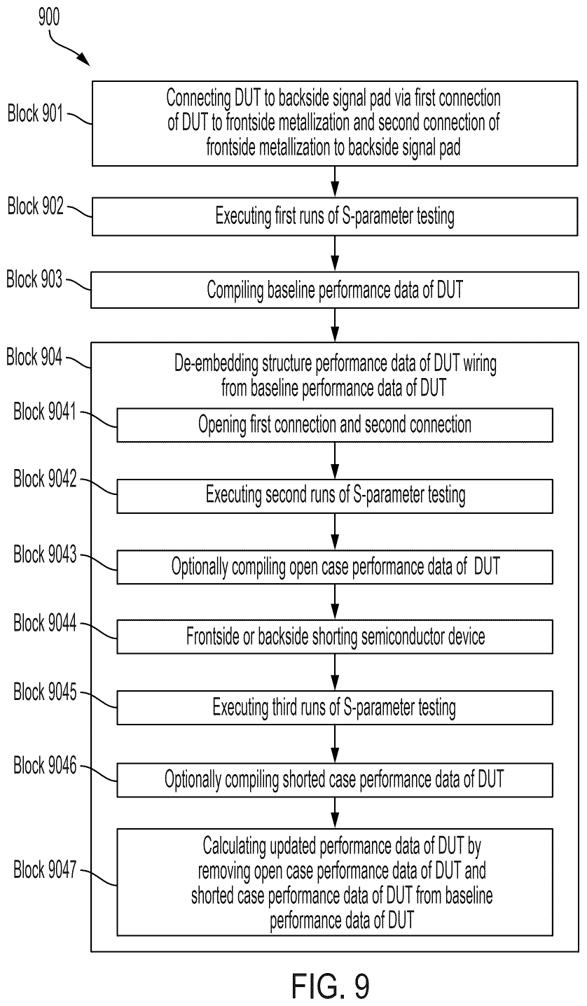

With reference to FIG. 9, a method 900 of conducting S-parameter testing of a semiconductor device, such as the semiconductor device 201 of FIGS. 2 and 3, is provided on a radio frequency (RF) characterization instrument under different frequency tests with ranges from about 5 MHz to about 100 GHz. The method 900 includes connecting a DUT to a backside signal pad via a first connection of the DUT to frontside metallization and a second connection of the frontside metallization to the backside signal pad (block 901), the connecting of block 901 being executed such that the second connection of the frontside metallization to the backside signal pad is provided as a single second connection or as multiple second connections. The method 900 further includes executing first runs of the S-parameter testing (block 902), compiling baseline performance data of the DUT from the first runs (block 903) and de-embedding structure performance data of DUT wiring from the baseline performance data (block 904). The de-embedding of the wiring performance of block 904 includes opening the first connection and the second connection (block 9041), executing second runs of the S-parameter testing (block 9042), optionally compiling open case performance data of the DUT from the second runs (block 9043), frontside or backside shorting of the semiconductor device (block 9044), executing third runs of the S-parameter testing (block 9045), optionally compiling shorted case performance data of the DUT from the third runs (block 9046) and calculating updated performance data of the DUT by removing the open case performance data of the DUT and the shorted case performance data of the DUT from the baseline performance data of the DUT (block 9047).

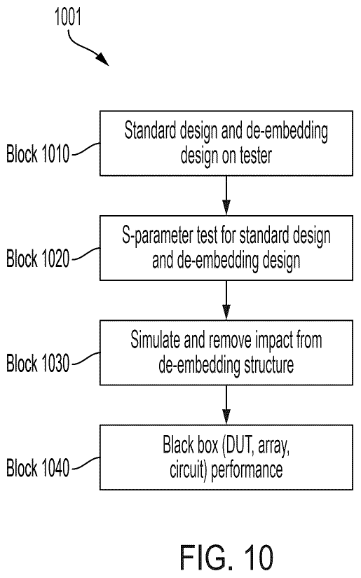

With reference to FIG. 10, a method 1001 of S-parameter testing is provided. The method 1001 includes a standard design and de-embedding design on a tester (block 1010) and then an S-parameter test for the standard design and the de-embedding design (block 1020). The method 1001 further includes simulating and removing an impact of wiring from the de-embedding structure (block 1030) and then determining black box performance (block 1040).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, electrically insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device for executing S-parameter testing, the semiconductor device comprising:
a first layer comprising a device under test (DUT);
a second layer comprising metallization;
a third layer comprising a backside power distribution network (BSPDN);
a signal pad; and
a connecting structure connecting the DUT to the signal pad via the metallization, the connecting structure comprising:
a first connecting section by which the DUT is connected to the metallization; and
a second connecting section that extends from the metallization, through the first layer and through the third layer to the signal pad and by which the metallization is connected to the signal pad.

2. The semiconductor device according to claim 1, wherein the first layer is a middle-of-line (MOL) layer, the third layer underlies the MOL layer and the signal pad underlies the third layer.

3. The semiconductor device according to claim 1, wherein:
the signal pad comprises a first signal pad and a second signal pad, and
the connecting structure comprises a first connecting structure connecting the DUT to the first signal pad via the metallization and a second connecting structure connecting the DUT to the second signal pad via the metallization.

4. The semiconductor device according to claim 1, further comprising:
ground pads; and
additional connecting structures respectively connecting the metallization to each of the ground pads.

5. The semiconductor device according to claim 1, wherein the first layer comprises a semiconductor material and an electrically insulating material underlying the semiconductor material and the BSPDN of the third layer underlies the electrically insulating material.

6. A semiconductor device for executing S-parameter testing, the semiconductor device comprising:
a first layer comprising first and second regions and first and second gates each of which crosses the first and second regions;
a second layer overlying the first layer and comprising metallization;
a third layer underlying the first layer and comprising a backside power distribution network (BSPDN);
a signal pad;
a first connecting structure connecting a section of the first gate defined between the first and second regions to the metallization; and
a second connecting structure connecting the metallization to the signal pad via a sub-section of the first region defined between the first and second gates.

7. The semiconductor device according to claim 6, wherein the section of the first gate comprises nanosheets and high-k metal gate material surrounding the nanosheets.

8. The semiconductor device according to claim 6, wherein the sub-section of the first region comprises dielectric material surrounding a portion of the second connecting structure.

9. The semiconductor device according to claim 6, wherein the first layer is a middle-of-line (MOL) layer, the second layer comprises a back-end-of-line (BEOL) layer to which a carrier wafer is attachable, the third layer underlies the MOL layer and the signal pad underlies the third layer.

10. The semiconductor device according to claim 6, further comprising interlayer dielectric (ILD) interposed between the first layer and the second layer, wherein:
the first connecting structure comprises a gate (CB) contact disposed in contact with the section of the first gate and a first additional contact disposed within the ILD and in contact with the CB contact and the metallization, and
the second connecting structure comprises a second additional contact disposed within the ILD and in contact with the metallization, CA/RV/BV contacts disposed in contact with the second additional contact and a backside (E1) metal disposed in contact with the CA/RV/BV contacts and the BSPDN.

11. The semiconductor device according to claim 6, wherein the first and second connecting structures are openable.

12. The semiconductor device according to claim 6, further comprising a metallization short.

13. The semiconductor device according to claim 6, further comprising a BSPDN short.

14. The semiconductor device according to claim 6, wherein the second connecting structure is provided as multiple backside second connecting structures.

15. The semiconductor device according to claim 14, wherein the first connecting structure and at least one of the multiple backside second connecting structures are openable.

16. A method of conducting S-parameter testing of a semiconductor device, the method comprising:
connecting a device under test (DUT) to a backside signal pad via a first connection of the DUT to frontside metallization and a second connection of the frontside metallization to the backside signal pad;
executing first runs of the S-parameter testing;
compiling baseline performance data of the DUT; and
isolating wiring performance data of DUT wiring from the baseline performance data.

17. The method according to claim 16, wherein the isolating of the wiring performance comprises:
opening the first connection and the second connection;
executing second runs of the S-parameter testing;
optionally compiling open case performance data of the DUT;
shorting the semiconductor device;
executing third runs of the S-parameter testing;
optionally compiling shorted case performance data of the DUT; and
calculating updated performance data of the DUT by removing the open case performance data of the DUT and the shorted case performance data of the DUT from the baseline performance data of the DUT.

18. The method according to claim 17, wherein the shorting comprises one of frontside shorting and backside shorting.

19. The method according to claim 16, wherein the connecting is executed such that the second connection of the frontside metallization to the backside signal pad is provided as multiple second connections.

20. The method according to claim 19, wherein the isolating of the wiring performance comprises:
opening the first connection and the multiple second connections;
executing second runs of the S-parameter testing;
shorting the semiconductor device; and
executing third runs of the S-parameter testing.
